(19) United States
(12) Patent Application Publication
(10) Pub. No.: US 2021/0234527 A1
(43) Pub. Date: Jul. 29, 2021

(54) Manufacturing Method for Piezoelectric Resonator and Piezoelectric Resonator

(71) Applicant: ANHUI ANUKI TECHNOLOGIES CO., LTD., Hefei, Anhui (CN)

(72) Inventors: Chengjie ZUO, Hefei, Anhui (CN); Jun HE, Hefei, Anhui (CN)

(21) Appl. No.: 16/096,265

(22) PCT Filed: Nov. 23, 2017
(86) PCT No.: PCT/CN2017/112543

§ 371 Date: Oct. 24, 2018

(30) Foreign Application Priority Data
Sep. 22, 2017 (CN) 201710864033.4
Sep. 22, 2017 (CN) 201721220998.1

(51) Int. Cl. H03H 9/02; H01L 41/18; H01L 41/37; H01L 41/27; H03H 3/02

(52) U.S. Cl. CPC H03H 9/02015; H01L 41/183; H03H 3/02; H01L 41/27; H01L 41/37

(57) ABSTRACT

Provided is a manufacturing method for piezoelectric resonator and a piezoelectric resonator, The manufacturing method includes forming a monocrystalline piezoelectric material layer on a first substrate; and forming a polycrystalline piezoelectric material layer on a surface far of the monocrystalline piezoelectric material layer away from the first substrate.

### TECHNICAL FIELD

The present disclosure relates to the field of piezoelectric device, and in particular to a manufacturing method for a piezoelectric resonator and a piezoelectric resonator.

### BACKGROUND

The film bulk acoustic resonator (FBAR), which is also known as the piezoelectric film resonator, has the principle to take use of the inverse piezoelectric effect of a piezoelectric film to convert the input high-frequency electrical signal into a certain frequency sound signal and produce resonance. The acoustic wave has a minimal loss at the resonant frequency. The piezoelectric resonance technology enables the manufacturing of more advanced electronic components and a wider range of application for communication technology.

Normally, a piezoelectric resonator includes two electrodes, which are oppositely set, and a piezoelectric film between the two electrodes. In the related art, the piezoelectric film is manufactured by monocrystalline aluminum nitride (AlN) piezoelectric material or polycrystalline AlN piezoelectric material. However, the monocrystalline AlN piezoelectric material is grown or deposited slow and has an internal stress hard to control. This adds technical problem and results in higher production cost. It is difficult to obtain the piezoelectric film with a large thickness, and it is difficult to manufacture the filter with higher performance in a low frequency band. The piezoelectric film formed by the growth of polycrystalline AlN piezoelectric material may have a larger thickness, and the low frequency resonator can be realized. However, the crystal quality of polycrystalline AlN is poor, which leads to a low quality factor Q and a low electromechanical coupling coefficient kₜ² and lowers the performance of the manufactured resonator.

### SUMMARY

The present disclosure provides a manufacturing method for a piezoelectric resonator and a piezoelectric resonator, which enables manufacturing a piezoelectric film with larger thickness more easily, manufacturing more easily a low frequency piezoelectric resonator, reducing the production cost and processing difficulty, improving the performance of the piezoelectric resonator and providing a higher crystallinity than polycrystalline piezoelectric materials.

In a first aspect, the present disclosure provides a manufacturing method for a piezoelectric resonator, which includes:

forming a monocrystalline piezoelectric material layer on a first substrate; and

forming a polycrystalline piezoelectric material layer on a surface of the monocrystalline piezoelectric material layer far away from the first substrate.

In a second aspect, the present disclosure further provides a piezoelectric resonator, which includes:

a monocrystalline piezoelectric material layer;

a polycrystalline piezoelectric material layer formed on a surface of the monocrystalline piezoelectric material layer;

a first electrode formed on a surface of the polycrystalline piezoelectric material layer far away from the monocrystalline piezoelectric material layer; and

a second electrode formed on a surface of the monocrystalline piezoelectric material layer far away from the polycrystalline piezoelectric material layer.

The present disclosure provides a manufacturing method for a piezoelectric resonator and a piezoelectric resonator. The monocrystalline piezoelectric material layer is formed on the first substrate, and the polycrystalline piezoelectric material layer is formed on the monocrystalline piezoelectric material layer. As such, a piezoelectric film, consisting of the monocrystalline piezoelectric material layer and the polycrystalline piezoelectric material layer, is formed. The adjustment to the ratio between the thickness of the monocrystalline piezoelectric material layer and the thickness of the polycrystalline piezoelectric material layer can optimize the comprehensive cost or performance of the piezoelectric resonator. The adjustment of the total thickness of piezoelectric film enables to realize the low frequency piezoelectric resonator. In the case of the low frequency piezoelectric resonator, a thinner monocrystalline piezoelectric layer and a thicker polycrystalline piezoelectric material layer can be formed to reduce production cost and process difficulty. At the same time, owing to the high crystallinity of monocrystalline piezoelectric materials, the polycrystalline piezoelectric material deposited on the monocrystalline of piezoelectric material layer has more regular arrangement of starting points of crystal lattice. This improves the crystallinity of polycrystalline piezoelectric material, and improves the performance of the piezoelectric resonator.

### BRIEF DESCRIPTION OF DRAWINGS

FIG. 1 is a flow diagram of a manufacturing method for a piezoelectric resonator according to embodiment one;

FIG. 2 to FIG. 3 are schematic diagrams illustrating a sectional structure of a piezoelectric resonator corresponding to steps of the manufacturing process according to embodiment one;

FIG. 4 is a flow diagram of a manufacturing method for a piezoelectric resonator according to embodiment two;

FIG. 5 is a flow diagram of a manufacturing method for a piezoelectric resonator according to embodiment three;

FIG. 6 is a flow diagram of a manufacturing method for a piezoelectric resonator according to embodiment four;

FIG. 7 is a flow diagram of a manufacturing method for a piezoelectric resonator according to embodiment five;

FIG. 8 to FIG. 11 are schematic diagrams illustrating a sectional structure of a piezoelectric resonator corresponding to steps of the manufacturing process of electrodes according to the embodiment five; and

FIG. 12 is a structure diagram of a piezoelectric resonator according to embodiment six.

### DETAILED DESCRIPTION

The present disclosure will be described by embodiments in conjunction with the accompanying drawings in the specification. It is understandable that the specific embodiments described here are only used to explain present disclosure, but not intended to limit the scope of the present disclosure.

### Embodiment One

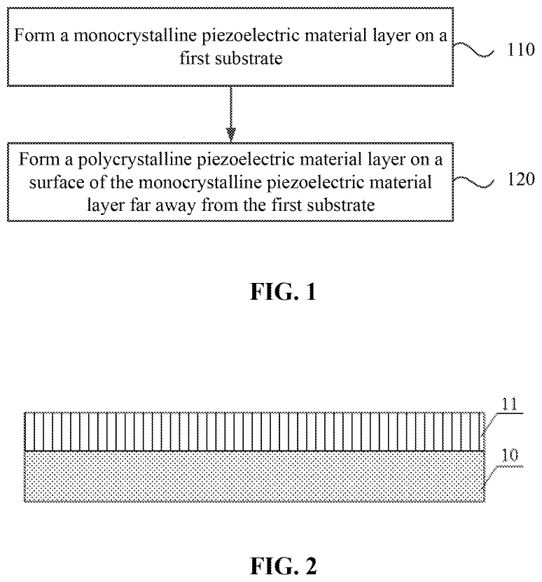

FIG. 1 is a flow diagram of a manufacturing method for a piezoelectric resonator according to embodiment one. FIG. 2 to FIG. 3 are schematic diagrams illustrating a sectional structure of a piezoelectric resonator corresponding to steps of the manufacturing process according to embodiment one. This embodiment can be applied to improve the performance of the piezoelectric resonator. As shown in FIG. 1, the manufacturing method for the piezoelectric resonator provided by this embodiment includes the steps described below.

In step 110, a monocrystalline piezoelectric material layer is formed on a first substrate.

As shown in FIG. 2, the monocrystalline piezoelectric material layer 11 is formed on the first substrate 10. The monocrystalline piezoelectric material layer 11 may be made of monocrystalline AlN and may be formed through epitaxial growth. For example, the epitaxial growth may include metallic organic chemical vapor deposition (MOCVD), which is also known as metal-organic chemical vapor phase epitaxy (MOVPE). Aluminum organic matter (generally, triethyl aluminum) may be selected as aluminum source. Ammonia gas is the nitrogen source for the reaction. The organic aluminum source and the excess ammonia gas may be transported through hydrogen gas, which is the carrier gas, and then is input into a vacuum reaction chamber. At a high temperature, the organic aluminum source reacts with ammonia gas to produce a monocrystalline piezoelectric material layer 11 of high quality. In addition, in one or more embodiments, the monocrystalline piezoelectric material may be zinc oxide (ZnO) or lithium tantalate (LiTaO₃) or lithium niobate (LiNbO₃), which is used to form the monocrystalline piezoelectric material layer 11 on the first substrate.

In step 120, a polycrystalline piezoelectric material layer is formed on a surface of the monocrystalline piezoelectric material layer far away from the first substrate.

As shown in FIG. 3, the polycrystalline piezoelectric layer 12 may be formed through depositing on the surface of the monocrystalline piezoelectric material layer 11 far away from the first substrate 10. The material of polycrystalline piezoelectric layer 12 and the material of monocrystalline piezoelectric material layer 11 may be the same or different. In one or more embodiments, the polycrystalline piezoelectric layer 12 may be made of polycrystalline AlN, and the deposition method may be radio frequency magnetron sputtering deposition technique. A highly pure Al target (99.99%) may be used. The highly pure argon (Ar) gas and the highly pure nitrogen (N₂) gas are respectively used as sputter gas and reaction gas. Based on the manufacturing of the monocrystalline AlN material layer of high quality, the polycrystalline AlN film may be manufactured by adjusting the experimental parameters such as work pressure, substrate temperature, N₂ flow and target-substrate distance. Because the monocrystalline piezoelectric material layer 11 is formed on the first substrate 10 and the monocrystalline piezoelectric material layer 11 has high crystallinity, the polycrystalline piezoelectric material 12 deposited on the surface of the monocrystalline piezoelectric material layer 11 has more regular arrangement of the starting points of crystal lattice. Therefore, the polycrystalline AlN piezoelectric material deposited on the first substrate 10 has higher crystallinity and better performance. In addition, in one or more embodiments, polycrystalline piezoelectric materials may be selected as zinc oxide (ZnO) or lead zirconium titanate piezoelectric ceramics (PZT) or lithium tantalate (LiTaO₃) or lithium niobate (LiNbO₃), which may be used in forming the polycrystalline piezoelectric layer 12 on the manufactured monocrystalline piezoelectric material layer 11.

This embodiment provides a manufacturing method for a piezoelectric resonator. The monocrystalline piezoelectric material layer is formed on the first substrate, and the polycrystalline piezoelectric material layer is formed on the monocrystalline piezoelectric material layer. A piezoelectric film, consisting of the monocrystalline piezoelectric material layer and the polycrystalline piezoelectric material layer, is formed. The adjustment of the ratio between the thickness of the monocrystalline piezoelectric material layer and the thickness of the polycrystalline piezoelectric material layer can optimize the comprehensive cost or performance of the piezoelectric resonator. The adjustment of the total thickness of piezoelectric film enables to realize the low frequency piezoelectric resonator. In the case of the low frequency piezoelectric resonator, a thinner monocrystalline piezoelectric layer and a thicker polycrystalline piezoelectric material layer can be formed to reduce production cost and process difficulty. At the same time, owing to the high crystallinity of monocrystalline piezoelectric material, the polycrystalline piezoelectric material deposited on the monocrystalline piezoelectric material layer has more regular arrangement of starting points of crystal lattice. This improves the crystallinity of the polycrystalline piezoelectric material layer, and improves the performance of the piezoelectric resonator.

In the technical solution described above, in one or more embodiments, the monocrystalline piezoelectric material layer 11 and the polycrystalline piezoelectric material layer 12 have a total thickness (i.e., the thickness of the piezoelectric film) greater than or equal to 1.5 μm, for which the resonant frequency of piezoelectric resonator is in the range of 100 MHz to 3 GHz (low frequency).

### Embodiment Two

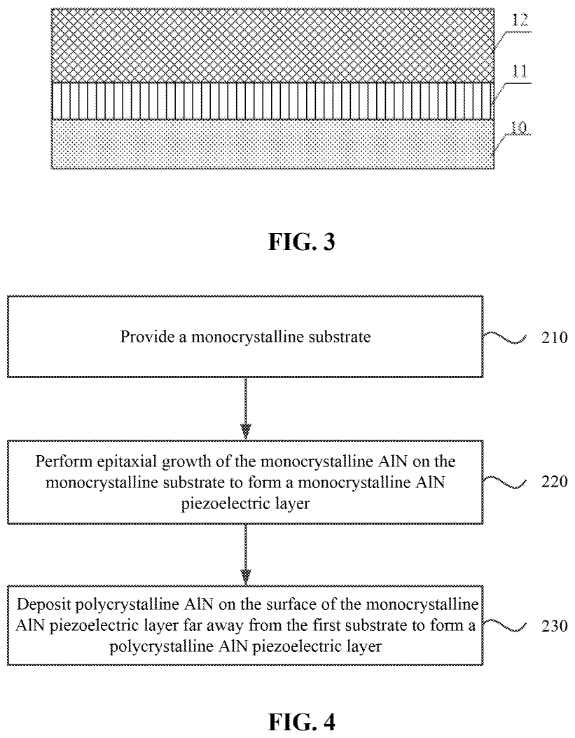

FIG. 4 is a flow diagram of a manufacturing method for a piezoelectric resonator according to embodiment two. This embodiment is an optimization on the basis of embodiment one. The step 110 in which a monocrystalline piezoelectric material layer is formed on a first substrate includes the steps described below.

A monocrystalline substrate is provided. An epitaxial growth of a monocrystalline aluminum nitride (AlN) is performed on the monocrystalline substrate to form a monocrystalline AlN piezoelectric layer. The monocrystalline AlN piezoelectric layer is the monocrystalline piezoelectric layer described above.

On the basis of the embodiments described above, in one or more embodiments, the material of the polycrystalline piezoelectric material layer is the same as the material of the monocrystalline piezoelectric material layer. On the basis of the embodiments described above, in one or more embodiments, the step in which the polycrystalline piezoelectric layer is formed on the surface of the monocrystalline piezoelectric material layer far away from the first substrate includes that the polycrystalline AlN piezoelectric layer is formed by depositing a polycrystalline AlN material on a surface of the monocrystalline AlN piezoelectric layer far away from the first substrate. As shown in FIG. 4, the method provided by this embodiment includes the steps described below.

In step 210: a monocrystalline substrate is provided.

If monocrystalline piezoelectric material layer 11 is made of monocrystalline AlN, the monocrystalline substrate provided may be a monocrystalline substrate made of silicon carbide (SiC) or sapphire or gallium nitride (GaN) or the like. AlN, which is an important III-V nitride, has a stable wurtzite structure. It decreases lattice mismatch and thermal mismatch in the AlN film manufactured on the above substrate, reduces the defect of the manufactured film and reduces the effect from the lattice mismatch on quality of the films.

The AlN material can maintain piezoelectricity at a high temperature, which makes AlN piezoelectric film device adaptive to high temperature working environments. Good chemical stability also enables AlN piezoelectric film to be adaptive to corrosive working environments. The AlN material also have good thermal conduction characteristics, which makes the acoustic device made of AlN do not have a reduced service life due to the heat from working. Therefore, AlN may be used for forming the monocrystalline piezoelectric material layer 11.

In step 220, the epitaxial growth of the monocrystalline AlN is performed on the monocrystalline substrate to form a monocrystalline AlN piezoelectric layer.

The epitaxial growth of the monocrystalline AlN is performed on the monocrystalline substrate. The epitaxial growth of monocrystalline AlN may be metallic organic chemical vapor deposition (MOCVD), or molecular beam epitaxy (MBE), or pulsed laser deposition (PLD), or radio frequency magnetron sputtering. In this embodiment, the monocrystalline AlN may be grown using MOCVD. In the growth of monocrystalline AlN, aluminum organic matter (generally triethyl aluminum) may be selected as aluminum source. Ammonia gas is the nitrogen source for the reaction. The organic aluminum source and the excess ammonia gas may be transported through hydrogen gas, which is the carrier gas, and input into a vacuum reaction chamber. The organic aluminum source reacts with the ammonia gas at a high temperature to produce a monocrystalline AlN film deposited on the surface of the substrate. The composition, growth thickness and uniformity of monocrystalline AlN film can be strictly controlled using MOCVD, and the monocrystalline AlN film of high quality is manufactured. This is suitable for mass production of the monocrystalline A1l film.

In step 230, polycrystalline AlN is deposited on the surface of the monocrystalline AlN piezoelectric layer far away from the first substrate to form a polycrystalline AlN piezoelectric layer.

The polycrystalline AlN is deposited on the surface of the monocrystalline AlN piezoelectric layer far away from the first substrate to form a polycrystalline AlN piezoelectric layer. The deposition may be radio frequency magnetron sputtering deposition. A highly pure Al target (99.99%) may be used. The highly pure argon (Ar) gas and the highly pure nitrogen (N₂) gas are respectively used as sputter gas and reaction gas. Based on the manufacturing of the monocrystalline AlN material layer of high quality, the polycrystalline AlN film may be manufactured by adjusting the experimental parameters such as work pressure, substrate temperature, N₂ flow and target-substrate distance. Because the monocrystalline piezoelectric material layer 11 is formed on the first substrate 10 and the monocrystalline piezoelectric material layer 11 has high crystallinity, the polycrystalline piezoelectric material deposited on the surface of the monocrystalline piezoelectric material layer 11 has more regular arrangement of the starting points of crystal lattice. Therefore, the polycrystalline AlN piezoelectric material deposited on the first substrate 10 has higher crystallinity and better performance.

In this embodiment, optionally, the monocrystalline AlN piezoelectric layer has a thickness less than 0.6 μm. When the monocrystalline AlN piezoelectric layer grows to more than 0.6 μm, the growth process takes longer time and more process problems come out. Under the restriction of process and production requirements, the growth of a thicker monocrystalline AlN piezoelectric layer greatly increases the production cost and reduce the yield. Therefore, it is difficult to manufacture a low frequency (e.g., below 1 GHz) piezoelectric resonator with high performance only using the monocrystalline AlN piezoelectric layer. In this embodiment, the monocrystalline AlN piezoelectric layer has a thickness less than 0.6 μm, and a polycrystalline AlN piezoelectric layer is deposited to increase the thickness of the piezoelectric film. For example, if the resonant frequency of the piezoelectric resonator needs to be around 2 GHz. Then the thickness of the piezoelectric film should be around 1.5 μm. The thickness of the monocrystalline AlN piezoelectric layer may be 0.5 μm or even smaller, and the thickness of the polycrystalline AlN piezoelectric layer may be 1 μm or more. In this way, the time of manufacturing monocrystalline AlN piezoelectric layer can be shorter, so that the whole manufacturing time is shortened and the process problems are reduced. In this way, the piezoelectric resonator with low frequency and high performance is realized.

This embodiment provides a manufacturing method for a piezoelectric resonator. The epitaxial growth of the monocrystalline AlN on the monocrystalline substrate can reduce the lattice mismatch and the thermal mismatch of AlN. It is beneficial to increase the crystallization of monocrystalline AlN and reduce the effect from the lattice mismatch on quality of the piezoelectric film. Comparing with the resonator and filter realized by only polycrystalline AlN (the mainstream mass production of products in related arts), it can reduce the loss and achieve a high Q and low insertion loss by depositing the polycrystalline AlN piezoelectric layer on the monocrystalline AlN piezoelectric layer.

### Embodiment Three

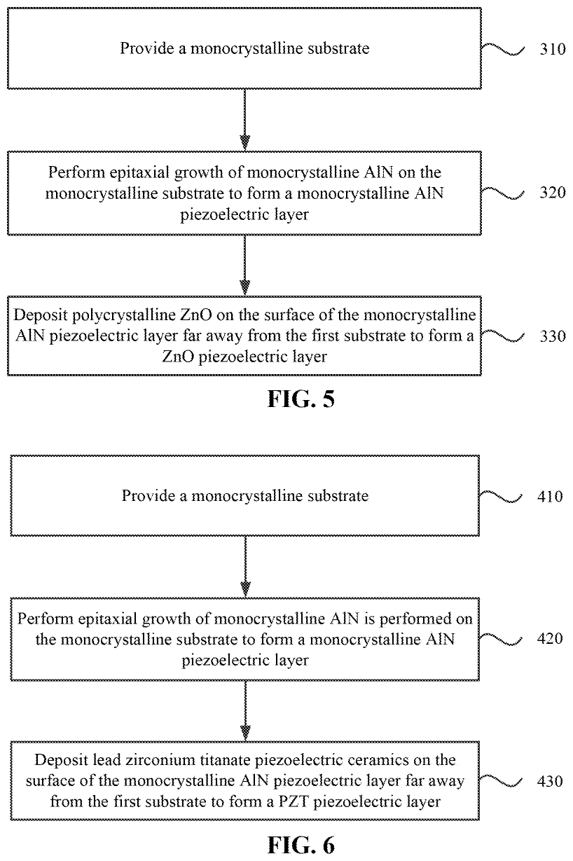

FIG. 5 is a flow diagram of a manufacturing method for a piezoelectric resonator according to embodiment three. Different from the embodiment two, in this embodiment, the material of the polycrystalline piezoelectric material layer and the material of the monocrystalline piezoelectric layer are different. Correspondingly, in one or more embodiments, the step in which a polycrystalline piezoelectric material layer is formed on the surface of the monocrystalline piezoelectric material layer far away from the first substrate includes that the polycrystalline zinc oxide (ZnO) is deposited on the surface of the monocrystalline piezoelectric material layer far away from the first substrate to form a ZnO piezoelectric layer. As shown in FIG. 5, the method provided by this embodiment includes the steps described below.

In step 310, a monocrystalline substrate is provided.

In step 320, an epitaxial growth of monocrystalline aluminum nitride (AlN) is performed on the monocrystalline substrate to form a monocrystalline AlN piezoelectric layer.

In step 330, polycrystalline zinc oxide (ZnO) is deposited on the surface of the monocrystalline AlN piezoelectric layer far away from the first substrate to form a ZnO piezoelectric layer.

The ZnO film has good piezoelectric properties (with the piezoelectric constant d₃₃≈12 μm/V) and also has a wurtzite structure. A good lattice match can be formed on the basis of a monocrystalline AlN film, and the effect from the lattice mismatch on quality of the polycrystalline ZnO film is reduced.

In one or more embodiments, polycrystalline zinc oxide (ZnO) is deposited on the surface of the monocrystalline AlN piezoelectric layer far away from the first substrate 10 to form a polycrystalline ZnO piezoelectric layer. The deposition may be radio frequency magnetron sputtering deposition. A highly pure ZnO ceramic target (99.99%). The highly pure O₂ and the highly pure Ar are respectively used as reaction gas and protection gas. Based on the manufacturing of the monocrystalline AlN material layer of high quality, the polycrystalline ZnO piezoelectric layer may be manufactured by adjusting the experimental parameters such as work pressure, gas flow, substrate temperature, deposition time and target-substrate distance. Because the first monocrystalline piezoelectric material layer 11 is formed on the first substrate 10 and the monocrystalline piezoelectric material layer 11 has high crystallinity, the polycrystalline piezoelectric material deposited on the surface of the monocrystalline piezoelectric material layer 11 has more regular arrangement of the starting points of crystal lattice. Therefore, polycrystalline ZnO piezoelectric materials deposited on the first substrate 10 has higher crystallinity and better performance.

This embodiment provides a manufacturing method for a piezoelectric resonator.

Comparing with the polycrystalline AlN piezoelectric layer, the polycrystalline ZnO deposited on the monocrystalline AlN piezoelectric layer can improve the electromechanical coupling coefficient kₜ² of the piezoelectric resonator and improve the performance of the piezoelectric resonator.

### Embodiment Four

FIG. 6 is a flow diagram of a manufacturing method for a piezoelectric resonator according to embodiment four. Different from the embodiment two, in this embodiment, the material of the polycrystalline piezoelectric material layer and the material of the monocrystalline piezoelectric layer are different. Correspondingly, the step in which the polycrystalline piezoelectric material layer is deposited on the surface of the monocrystalline piezoelectric material layer far away from the first substrate includes that lead zirconium titanate (PZT) piezoelectric ceramics is deposited on the surface of the monocrystalline piezoelectric layer far away from the first substrate to form a PZT piezoelectric layer.

In step 410, a monocrystalline substrate is provided.

In step 420, an epitaxial growth of monocrystalline aluminum nitride (AlN) is performed on the monocrystalline substrate to form a monocrystalline AlN piezoelectric layer.

In step 430, lead zirconium titanate piezoelectric ceramics is deposited on the surface of the monocrystalline AlN piezoelectric layer far away from the first substrate to form a PZT piezoelectric layer.

The PZT film, having the mechanical-electrical coupling performance and a high electromechanical coupling coefficient kₜ², is a preferred material for manufacturing wideband filters. In one or more embodiments, PZT is deposited on the surface of the monocrystalline AlN piezoelectric layer far away from the first substrate to form a PZT piezoelectric layer. The deposition may be pulsed laser deposition. For example, PZT piezoelectric ceramics with zirconium titanium ratio Zr/Ti=52/48 is used as the target material. A PZT film is manufactured, using pulsed laser deposition and with the fluorinated krypton KrF pulse laser, on the manufactured monocrystalline AlN piezoelectric layer. In the experiment, vacuumization is performed and then oxygen gas is introduced to reach a certain pressure. The substrate, on which a high quality monocrystalline AlN piezoelectric layer is manufactured, is heated to a certain temperature, and the pulsed KrF laser ray is injected to the PZT target at an angle of 45° C., such that PZT atoms are discharged from the target material and are deposited on the substrate. Then the temperature decreases to room temperature to crystallize the film, so as to have the PZT film manufactured. The PZT piezoelectric layer may be manufactured by adjusting the experimental parameters such as work pressure, substrate temperature, deposition time and target-substrate distance.

This embodiment provides a manufacturing method for a piezoelectric resonator. Comparing with the polycrystalline AlN piezoelectric layer, the deposition of a PZT piezoelectric layer on the monocrystalline AlN piezoelectric layer can improve the electromechanical coupling coefficient kₜ² of the piezoelectric resonator and improve the performance of the piezoelectric resonator.

### Embodiment Five

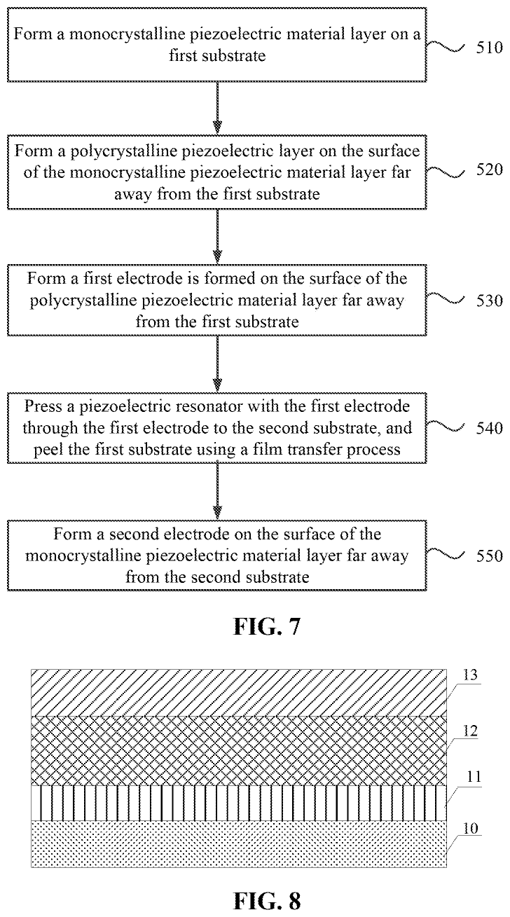

FIG. 7 is a flow diagram of a manufacturing method for a piezoelectric resonator according to embodiment five. FIG. 8 to FIG. 11 are schematic diagrams illustrating a sectional structure of a piezoelectric resonator corresponding to steps of the manufacturing process of electrodes according to the embodiment five. In this embodiment, after a polycrystalline piezoelectric material layer is formed on the surface of the monocrystalline piezoelectric material layer far away from the first substrate, the manufacturing method further includes the followings, based on the embodiments described above. A first electrode is formed on the surface of the polycrystalline piezoelectric material layer far away from the first substrate. A piezoelectric resonator with the first electrode is pressed on a second substrate by pressing the first electrode and the second substrate together, and the first substrate is peeled using a film transfer process. A second electrode is formed on the surface of the monocrystalline piezoelectric material layer far away from the second substrate. As shown in FIG. 7, the method provided by this embodiment includes the steps described below.

In step 510, a monocrystalline piezoelectric material layer is formed on the first substrate.

In step 520, a polycrystalline piezoelectric layer is formed on the surface of the monocrystalline piezoelectric material layer far away from the first substrate.

In step 530, a first electrode is formed on the surface of the polycrystalline piezoelectric material layer far away from the first substrate.

As shown in FIG. 8, a first electrode 12 is formed on the surface of the polycrystalline piezoelectric material layer 12 far away from the first substrate 10 through for example magnetron sputtering. A layer of one material or a combination of multiple materials selected from a group consisting of aluminum (Al), copper (Cu), silver (Ag), tungsten (W), platinum (Pt), titanium (Ti) and molybdenum (Mo), may be deposited on the polycrystalline piezoelectric material layer 12. The first electrode 13 may have a similar shape to the substrate.

In step 540, a piezoelectric resonator with the first electrode is pressed through the first electrode to the second substrate, and the first substrate is peeled using the film transfer process.

As shown in FIG. 9, for example, the first substrate 10, the monocrystalline piezoelectric material layer 11, the polycrystalline piezoelectric material layer 12 and the first electrode 13 are turned over firstly, and the first electrode 13 is mechanically pressed to the second substrate 14. In this way, the surface of the first electrode 13 far away from the monocrystalline piezoelectric material layer 11 and the surface of the second substrate 14 form a firm structure by bonding. Secondly, the monocrystalline piezoelectric material layer 11 is peeled, using laser lift-off or plasma lift-off technique, from the first substrate 10. The peel ratio of laser lift-off or plasma lift-off technique is higher. At the same time, it is possible to avoid the rupture of film or the rupture of substrate in the process of peeling.

In step 550, a second electrode is formed on the surface of the monocrystalline piezoelectric material layer far away from the second substrate.

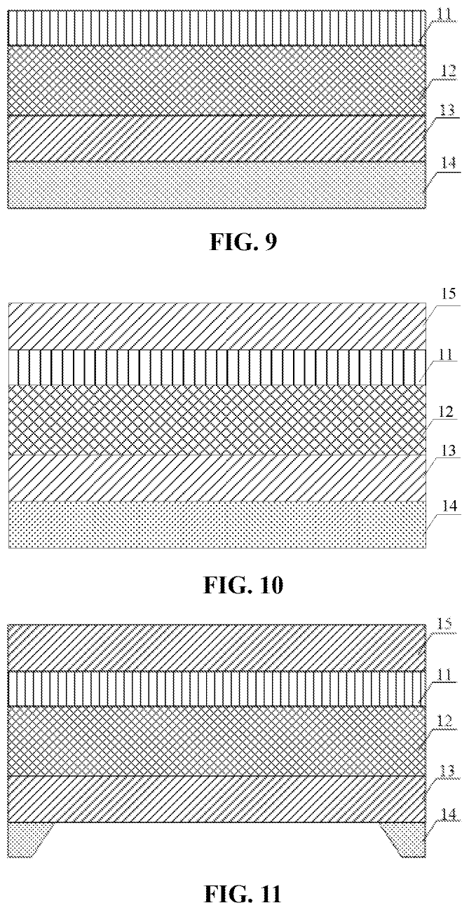

As shown in FIG. 10, on the basis of embodiments described above, an electrode structure, which is made of one material or a combination of multiple materials selected from a group consisting aluminum (Al), copper (Cu), silver (Ag), tungsten (W), platinum (Pt), titanium (Ti) and molybdenum (Mo), is formed on the surface of the monocrystalline piezoelectric material layer 11 far away from the first electrode 13 using magnetron sputtering. The electrode structure is the second electrode 15. In one or more embodiments, the material of the first electrode 13 and the material of the second electrode 15 can be aluminum (Al) and platinum (Pt). The thickness of the first electrode 13 and the thickness of the second electrode 15 are determined according to the actual production requirements. At the same time, the shape of the electrodes may be similar or dissimilar to the substrate or piezoelectric film, and the specific structure is determined according to the actual situation. The second substrate 14 may be a silicon slice, and may be a layer of sacrificial material used as a temporary support structure. Finally, as shown in FIG. 5, part of the material is removed from the second substrate 14 using etching technique, so as to form a cavity.

During the manufacturing of the polycrystalline piezoelectric resonator, a molybdenum electrode is formed on the substrate and a piezoelectric film is formed on the molybdenum electrode. At this time, the internal stress in the resonator is relatively easy to control, making the mass production based on polycrystalline AlN possible. The internal stress of the resonator is more difficult to control and the yield is lower with an electrode formed by other metals.

This embodiment provides a manufacturing method for a piezoelectric resonator. The electrode formed is not confined to the molybdenum electrode, and a variety of conductive materials may be selected. The first electrode is formed after the piezoelectric film is manufactured, and the second electrode is formed on the other surface of the piezoelectric film after the first substrate is peeled. The piezoelectric film is not directly formed on the second electrode, the metal materials of the electrodes on both surfaces of the piezoelectric material may be selected according to different process and performance requirements, in order to achieve the best cost-effective. For example, aluminum has a smaller resistivity than molybdenum, which can reduce the parasitic resistance of the resonator and improve the Q value of the resonator.

### Embodiment Six

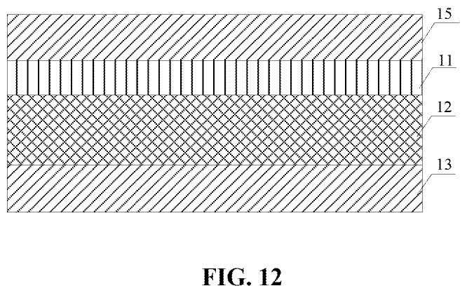

FIG. 12 is a structure diagram of a piezoelectric resonator according to embodiment six. The piezoelectric resonator may be manufactured using any of manufacturing methods for a piezoelectric resonator provided by the embodiments of the present disclosure. As shown in FIG. 12, the piezoelectric resonator includes: a monocrystalline piezoelectric material layer 11, a polycrystalline piezoelectric material layer 12, a first electrode 13 and a second electrode 15.

The polycrystalline piezoelectric material layer 12 is formed on a surface of the monocrystalline piezoelectric material layer 11. The first electrode 13 is formed on a surface of the polycrystalline piezoelectric material layer 12 far away from the monocrystalline piezoelectric material layer 11. The second electrode 15 is formed on a surface of the monocrystalline piezoelectric material layer 11 far away from the polycrystalline piezoelectric material layer 12.

The monocrystalline piezoelectric material layer 11 may be made of monocrystalline AlN. Since AlN has a high velocity of acoustic wave, the AlN film can be used to make a high frequency resonator (GHz). Furthermore, The AlN material, which has low loss and enables to achieve a high quality factor (Q) value, can be used in complex work environments.

In one or more embodiments, the material of the polycrystalline piezoelectric material layer 12 and the material of the monocrystalline piezoelectric material layer 11 may be the same or different. For example, the polycrystalline piezoelectric material layer 12 may be made of polycrystalline AlN, or lead zirconium titanate piezoelectric ceramics, or polycrystalline zinc oxide, or lithium tantalite, or lithium niobate. The electromechanical coupling coefficient (kₜ²) of LiNbO₃ is higher. The electromechanical coupling coefficient ((kₜ²) is an important physical quantity to measure the piezoelectric properties of piezoelectric materials, and determines the bandwidth of the filter. Both LiNbO₃ and PZT have high electromechanical coupling coefficients (kₜ²), which makes the achievable bandwidth wider. The kₜ² of zinc oxide (ZnO) is 7.5%. The kₜ² of AlN is 6.5%. In addition, the quality factor (Q) is an important indicator of the filter device, and the Q of the piezoelectric resonator depends on the inherent loss of the piezoelectric film material and the loss of the bulk acoustic wave in the substrate. In this aspect, the loss of AlN and the loss of ZnO are better than that of PZT.

In one or more embodiments, the monocrystalline piezoelectric material layer has a thickness less than 0.6 μm.

In one or more embodiments, the monocrystalline piezoelectric material layer and the polycrystalline piezoelectric material layer have a total thickness greater than or equal to 1.5 μm.

In one or more embodiments, the first electrode 13 and the second electrode 15 may be made of one material or a combination of multiple materials selected from a group consisting aluminum (Al), copper (Cu), silver (Ag), tungsten (W), platinum (Pt), titanium (Ti) and molybdenum (Mo). The main reason for choosing Al and Pt is that the resistivity of Al material is small, and the mechanical properties of Pt electrode and W electrode are better in the AlN resonator.

As for the contents not described in detail in this embodiment, reference may be made to the method embodiments described above. The contents will not be repeated.

This embodiment provides a piezoelectric resonator applied in communications where the resonance frequency is in a low frequency band. Comparing with the related art, this embodiment provides a piezoelectric resonator, in which the piezoelectric material layer is formed on a surface of the monocrystalline piezoelectric material layer. This enables the piezoelectric material layer to reach a certain thickness in a relatively short time. It shortens the process time, reduces the production cost and realizes the resonance frequency in the low frequency band, while maintaining the performance of a high Q value and a high electromechanical coupling coefficient (kₜ²). Furthermore, the bandwidth of the filter is broadened, and the range of applications is increased.

### INDUSTRIAL APPLICABILITY

The present disclosure provides a manufacturing method for a piezoelectric resonator and a piezoelectric resonator. Owing to the high crystallinity of monocrystalline piezoelectric material, the polycrystalline piezoelectric material deposited on the monocrystalline of piezoelectric material layer has more regular arrangement of starting points of crystal lattice, which improves the crystallinity of polycrystalline piezoelectric material and improves the performance of the piezoelectric resonator.

1. A manufacturing method for a piezoelectric resonator, comprising:
forming a monocrystalline piezoelectric material layer on a first substrate; and
forming a polycrystalline piezoelectric material layer on a surface of the monocrystalline piezoelectric material layer far away from the first substrate.

2. The manufacturing method according to claim 1, wherein the step of forming a monocrystalline piezoelectric material layer on the first substrate comprises:
providing a monocrystalline substrate; and
performing an epitaxial growth of a monocrystalline aluminum nitride (AlN) on the monocrystalline substrate to form a monocrystalline AlN piezoelectric layer.

3. The manufacturing method according to claim 2, wherein a material of the polycrystalline piezoelectric material layer is the same as a material of the monocrystalline piezoelectric material layer.

4. The manufacturing method according to claim 3, wherein the step of forming a polycrystalline piezoelectric material layer on a surface of the monocrystalline piezoelectric material layer far away from the first substrate comprises:
depositing polycrystalline AlN on a surface of the monocrystalline AlN piezoelectric layer far away from the first substrate to form a polycrystalline AlN piezoelectric layer.

5. The manufacturing method according to claim 2, wherein a material of the polycrystalline piezoelectric material layer is different from a material of the monocrystalline piezoelectric material layer.

6. The manufacturing method according to claim 5, wherein the step of forming a polycrystalline piezoelectric material layer on a surface of the monocrystalline piezoelectric material layer far away from the first substrate comprises:
depositing lead zirconium titanate piezoelectric ceramics (PZT) or polycrystalline zinc oxide (ZnO) or lithium tantalate (LiTaO₃) or lithium niobate (LiNbO₃) on a surface of the monocrystalline AlN piezoelectric layer far away from the first substrate to form a PZT piezoelectric layer or a ZnO piezoelectric layer or a LiTaO₃ piezoelectric layer or a LiNbO₃ piezoelectric layer.

7. The manufacturing method according to claim 2, wherein the monocrystalline AlN piezoelectric layer has a thickness less than 0.6 μm.

8. The manufacturing method according to claim 1, wherein the monocrystalline piezoelectric material layer and the polycrystalline piezoelectric material layer have a total thickness greater than or equal to 1.5 μm.

9. The manufacturing method according to claim 1, wherein after the step of forming a polycrystalline piezoelectric material layer on a surface of the monocrystalline piezoelectric material layer far away from the first substrate, the manufacturing method further comprises:
forming a first electrode on a surface of the polycrystalline piezoelectric material layer far away from the first substrate;
pressing the first electrode and a second substrate together and peeling the first substrate using a film transfer process; and
forming a second electrode on a surface of the monocrystalline piezoelectric material layer far away from the second substrate.

10. The manufacturing method according to claim 9, wherein at least one of the first electrode and the second electrode is made of one material or a combination of a plurality of materials selected from a group consisting of aluminum (Al), copper (Cu), silver (Ag), tungsten (W), platinum (Pt), titanium (Ti) and molybdenum (Mo).

11. A piezoelectric resonator, comprising:
a monocrystalline piezoelectric material layer;
a polycrystalline piezoelectric material layer formed on a surface of the monocrystalline piezoelectric material layer;
a first electrode formed on a surface of the polycrystalline piezoelectric material layer far away from the monocrystalline piezoelectric material layer; and
a second electrode formed on a surface of the monocrystalline piezoelectric material layer far away from the polycrystalline piezoelectric material layer.

12. The piezoelectric resonator according to claim 11, wherein the monocrystalline piezoelectric material layer is made of monocrystalline aluminum nitride (AlN).

13. The piezoelectric resonator according to claim 12, wherein the polycrystalline piezoelectric material layer is made of polycrystalline AlN or lead zirconium titanate piezoelectric ceramics or polycrystalline zinc oxide or lithium tantalate or lithium niobate.

14. The piezoelectric resonator according to claim 12, wherein the monocrystalline piezoelectric material layer has a thickness less than 0.6 μm.

15. The piezoelectric resonator according to claim 11, wherein the monocrystalline piezoelectric material layer and the polycrystalline piezoelectric material layer have a total thickness greater than or equal to 1.5 μm.

16. The piezoelectric resonator according to claim 11, wherein at least one of the first electrode and the second electrode is made of one material or combination of a plurality of materials selected from a group consisting of aluminum (Al), copper (Cu), silver (Ag), tungsten (W), platinum (Pt), titanium (Ti) and molybdenum (Mo).

17. The manufacturing method according to claim 3, wherein the monocrystalline AlN piezoelectric layer has a thickness less than 0.6 μm.

18. The manufacturing method according to claim 4, wherein the monocrystalline AlN piezoelectric layer has a thickness less than 0.6 μm.

19. The manufacturing method according to claim 5, wherein the monocrystalline AlN piezoelectric layer has a thickness less than 0.6 μm.

20. The piezoelectric resonator according to claim 13, wherein the monocrystalline piezoelectric material layer has a thickness less than 0.6 μm.
